(19) United States
(12) Patent Application Publication
(10) Pub. No.: US 2026/0040605 A1
(43) Pub. Date: Feb. 5, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Dongwoo Kim, Suwon-si (KR); Hyunwoo Kim, Suwon-si (KR); Dongsuk Shin, Suwon-si (KR); Tae-Yeon Shin, Suwon-si (KR); Kyungbin Chun, Suwon-si (KR)

(21) Appl. No.: 19/012,067

(22) Filed: Jan. 7, 2025

(30) Foreign Application Priority Data
Jul. 30, 2024 (KR) 10-2024-0100766

(51) Int. Cl. H10D 30/00; H10D 30/01

(52) U.S. Cl. CPC H10D 30/502; H10D 30/0198

(57) ABSTRACT

A semiconductor device includes a power transmission network layer on a first surface of a substrate, a source/drain pattern on the substrate, the source/drain pattern including a first pattern including a first material and a second pattern including a second material that is different from the first material, and a backside conductive contact that extends into the substrate and into the source/drain pattern. The backside conductive contact includes a first region that extends into the first pattern of the source/drain pattern and a second region on the first region. The second region of the backside conductive contact has a second width that is greater than a first width of the first region of the backside conductive contact in a direction parallel to a second surface of the substrate.

### CROSS-REFERENCE TO RELATED APPLICATIONS

This U.S. non-provisional patent application claims priority under 35 U.S.C. § 119 to Korean Patent Application No. 10-2024-0100766 filed on Jul. 30, 2024, in the Korean Intellectual Property Office, the entire contents of which are hereby incorporated by reference.

### BACKGROUND OF THE INVENTION

The inventive concept relates to a semiconductor device and a method of manufacturing the same, and more specifically, relates to a semiconductor device including a field effect transistor and a method of manufacturing the same.

A semiconductor device may include an integrated circuit including metal-oxide-semiconductor field effect transistors (MOSFETs). As sizes and design rules of semiconductor devices have been reduced, sizes of MOSFETs have also been scaled down. Operating characteristics of semiconductor devices may be deteriorated by the scale down of the MOSFETs. Thus, various research is being conducted for semiconductor devices capable of overcoming limitations caused by a high integration density and of improving performance.

### SUMMARY

An object of the inventive concept is to provide a semiconductor device with improved electrical characteristics and a method of manufacturing the same.

The problem to be solved by the inventive concept is not limited to the problems mentioned above, and other problems not mentioned may be clearly understood by those skilled in the art from the description below.

A semiconductor device according to some embodiments of the inventive concept may include a power transmission network layer on a first surface of a substrate, a source/drain pattern on the substrate, the source/drain pattern including a first pattern including a first material and a second pattern including a second material that is different from the first material, and a backside conductive contact that extends into the substrate and into the source/drain pattern, wherein the backside conductive contact includes a first region that extends into the first pattern of the source/drain pattern and a second region on the first region of the backside conductive contact, and the second region of the backside conductive contact has a second width that is more than a first width of the first region of the backside conductive contact in a direction parallel to a second surface of the substrate.

A semiconductor device according to some embodiments of the inventive concept may include a power transmission network layer on a first surface of a substrate, a source/drain pattern on the substrate, the source/drain pattern including a first pattern including a first material and a second pattern including a second material that is different from the first material, a backside conductive contact that extends into the substrate and into the source/drain pattern, and an interface layer between the first pattern of the source/drain pattern and the backside conductive contact. The interface layer includes a first region that has a first width and a second region that has a second width that is greater than the first width in a direction parallel to an second surface of the substrate.

A semiconductor device according to some embodiments of the inventive concept may include a power transmission network layer on a first surface of a substrate, a source/drain pattern on the substrate, the source/drain pattern including a first pattern including a first material and a second pattern including a second material that is different from the first material, a channel pattern on a side surface of the source/drain pattern, the channel pattern including a plurality of semiconductor patterns on the substrate, a gate electrode on the channel pattern, a backside conductive contact that extends into the substrate and into the source/drain pattern, and an interface layer between the first pattern of the source/drain pattern and the backside conductive contact. The backside conductive contact includes a first region that extends into the first pattern of the source/drain pattern and a second region on the first region, and the second region of the backside conductive contact has a second width that is more than a first width of the first region of the backside conductive contact in a direction parallel to a second surface of the substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor device according to some embodiments of the inventive concept.

FIG. 2A is a cross-sectional view corresponding to line A-A′ of FIG. 1.

FIG. 2B is a cross-sectional view corresponding to line B-B′ of FIG. 1.

FIG. 3A is an enlarged view corresponding to ‘P1’ of FIG. 2A.

FIG. 3B is an enlarged view corresponding to ‘P2’ of FIG. 2B.

FIGS. 4A, 4B, 5, 6A, 6B, 6C, 7, 8A, 8B, 8C, 9A, and 9B are views illustrating a method of manufacturing a semiconductor device according to some embodiments of the inventive concept.

### DETAILED DESCRIPTION

Hereinafter, to explain the inventive concept in detail, embodiments according to the inventive concept will be described with reference to the attached drawings.

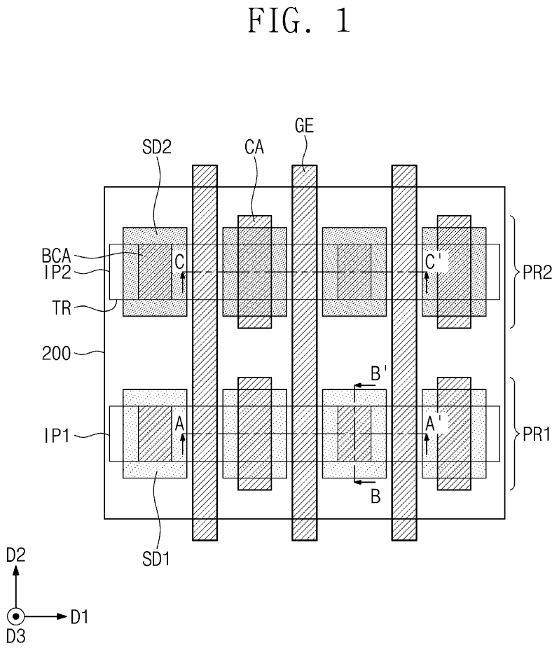

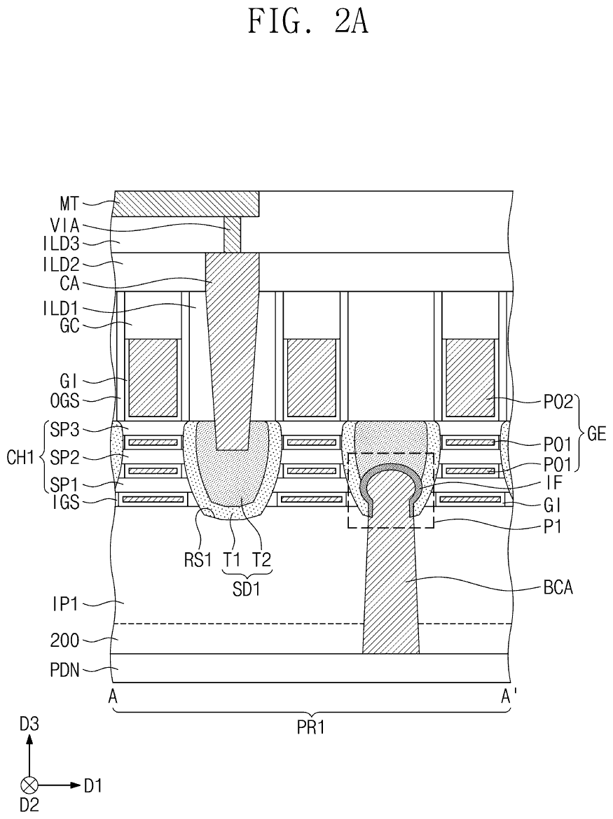

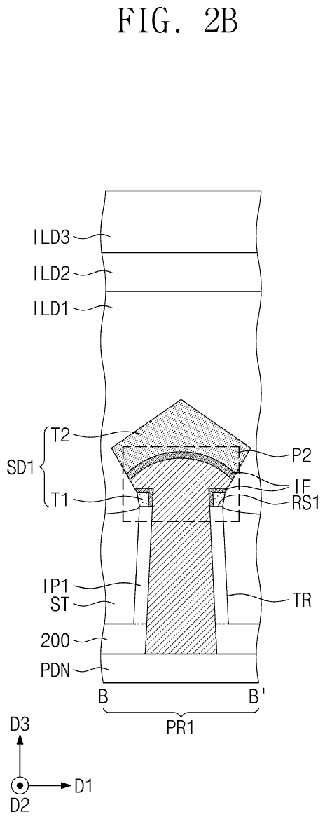

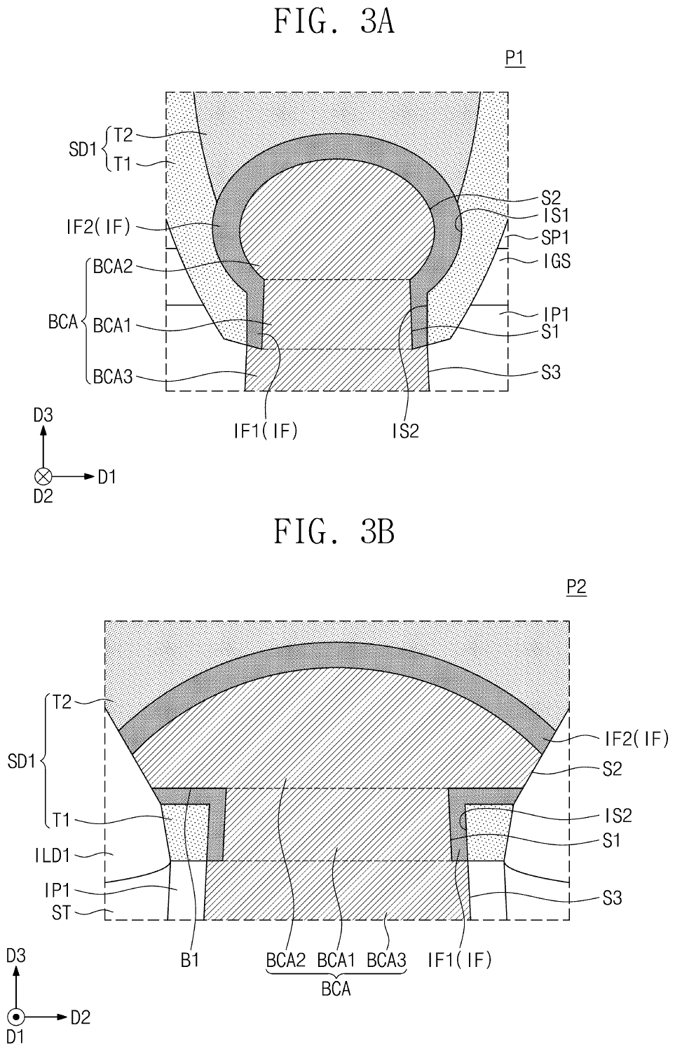

FIG. 1 is a plan view illustrating a semiconductor device according to some embodiments of the inventive concept. FIG. 2A is a cross-sectional view corresponding to line A-A′ of FIG. 1. FIG. 2B is a cross-sectional view corresponding to line B-B′ of FIG. 1. FIG. 3A is an enlarged view corresponding to ‘P1’ of FIG. 2A. FIG. 3B is an enlarged view corresponding to ‘P2’ of FIG. 2B.

Referring to FIGS. 1, 2A, and 2B, a substrate 200 including each of a first region PR1 and a second region PR2 may be provided. For example, the substrate 200 may include a silicon-based insulating layer. In other words, the substrate 200 may be an insulating substrate. For example, the substrate 200 may include at least one of a silicon oxide layer (SiO₂), a silicon nitride layer (SiN), and a silicon oxynitride layer (SiON). In the present disclosure, an expression, such as “A or B”,”, “at least one of A and B”, “at least one of A or B”, “A, B, or C”, “at least one of A, B, and C”, and “at least one of A, B, or C”, may include all of the possible combinations of the listed items together. The term “and/or” includes any and all combinations of one or more of the associated listed items.

The first region PR1 and the second region PR2 may respectively extend in a first direction D1 and may be spaced apart from each other in a second direction D2. The first and second directions D1 and D2 may be parallel to an upper surface of the substrate 200 and may intersect (e.g., be orthogonal to) each other. For example, the first region PR1 may be an NMOSFET region, and the second region PR2 may be a PMOSFET region.

The first region PR1 may form one logic cell together with the second region PR2. In this specification, a logic cell may mean a logic element (e.g., AND, OR, XOR, XNOR, inverter, etc.) that performs a specific function. That is, the logic cell may include transistors for forming a logic element and wirings that connect the transistors to each other. In the drawing, one logic cell is illustrated, but is not limited thereto.

Each of insulating patterns IP1 and IP2 may be defined by a trench TR on an upper portion of the substrate 200. Each of the insulating patterns IP1 and IP2 may be a portion of the substrate 200. For example, the portion of the substrate 200 may protrude in a third direction D3. The third direction D3 may be a direction perpendicular to the upper surface of the substrate 200. For convenience of explanation, unless otherwise specified, the substrate 200 in this specification is defined as a portion other than the portion of the substrate 200 (i.e., the insulating patterns IP1 and IP2). The insulating patterns IP1 and IP2 may include a first insulating pattern IP1 provided on the first region PR1 and the second insulating pattern IP2 provided on the second region PR2. The first and second insulating patterns IP1 and IP2 may respectively extend in the first direction D1 and may be adjacent to each other in the second direction D2.

A device isolation pattern ST may be provided on the substrate 200 and may fill the trench TR. The device isolation pattern ST may include an insulating material.

A first channel pattern CH1 may be provided on the first insulating pattern IP1. A plurality of first channel patterns CH1 may be provided. The first channel patterns CH1 may be disposed to be spaced apart from each other in the first direction D1. The first channel pattern CH1 may include a first semiconductor pattern SP1, a second semiconductor pattern SP2, and a third semiconductor pattern SP3 which are adjacent to each other in the third direction D3, but are not limited thereto. For example, the first channel pattern CH1 may include four or more semiconductor patterns. Each of the first to third semiconductor patterns SP1, SP2, and SP3 may include crystalline silicon. A second channel pattern (not shown) may be provided on the second insulating pattern IP2. The characteristics of the second channel pattern may be the same as/similar to the characteristics of the first channel pattern CH1.

First recesses RS1 may be defined between the first channel patterns CH1. Although not shown in the drawing, second recesses (not shown) having a shape identical to/similar to the first recesses RS1 may be defined between the second channel patterns.

A first source/drain pattern SD1 may be provided on the first insulating pattern IP1, and a second source/drain pattern SD2 may be provided on the second insulating pattern IP2. The first source/drain pattern SD1 may partially or completely fill the first recess RS1, and the second source/drain pattern SD2 may partially or completely fill the second recess. Each of the first and second source/drain patterns SD1 and SD2 may be electrically connected to the first to third semiconductor patterns SP1, SP2, and SP3.

The first source/drain pattern SD1 may include at least one of a semiconductor element (e.g., Si) that is the same as the first channel pattern CH1 and a semiconductor element (e.g., SiGe) that has a lattice constant greater than a lattice constant of the semiconductor element of the first channel pattern CH1. The first source/drain pattern SD1 may be an impurity region having a first conductivity type (e.g., n-type).

The first source/drain pattern SD1 may include a first pattern T1 that covers, overlaps, or is on an inner surface of the first recess RS1 and a second pattern T2 that fills the first recess RS1 on the first pattern T1. The first pattern T1 and the second pattern T2 of the first source/drain pattern SD1 may include different materials. A material included in the first pattern T1 of the first source/drain pattern SD1 may have an etching selectivity with respect to a material included in the second pattern T2 of the first source/drain pattern SD1. For example, the first pattern T1 of the first source/drain pattern SD1 may include at least one of SiGe, SiGeC, SiB, and/or SiC. For example, the second pattern T2 of the first source/drain pattern SD1 may include Si. The first pattern T1 of the first source/drain pattern SD1 may be interposed between the second pattern T2 and the first channel pattern CH1, thereby preventing diffusion of the material in the second pattern T2 into the first channel pattern CH1. For example, when the first pattern T1 of the first source/drain pattern SD1 includes SiGeC, an atomic concentration of Ge may be 4 at % to 10 at %, and an atomic concentration of C may be 0.02 at % to 0.2 at %.

The second source/drain patterns SD2 may include a semiconductor element (e.g., SiGe) having a lattice constant greater than a lattice constant of the semiconductor element of the second channel pattern. Accordingly, a pair of second source/drain patterns SD2 may provide compressive stress to the second channel pattern therebetween. The second source/drain pattern SD2 may be an impurity region having a second conductivity type (e.g., p-type).

A gate electrode GE may be provided on each of the first channel pattern CH1 and the second channel pattern, and may cross each of the first channel pattern CH1 and the second channel pattern. A plurality of gate electrodes GE may be provided. The gate electrodes GE may be spaced apart from each other in the first direction D1 and may extend in the second direction D2, respectively.

The gate electrode GE may include an inner electrode PO1 and an outer electrode PO2. The inner electrode PO1 of the gate electrode GE may be provided between the uppermost semiconductor pattern among the plurality of semiconductor patterns SP1, SP2, and SP3 and the insulating pattern IP1 and IP2. The outer electrode PO2 of the gate electrode GE may be provided on the uppermost semiconductor pattern. For example, the inner electrode PO1 of the gate electrode GE may include three electrode portions, but is not limited thereto. For example, the inner electrode PO1 of the gate electrode GE may include four or more electrode portions.

The gate electrode GE may include a first metal pattern, and a second metal pattern on the first metal pattern. The first metal pattern may include a work function metal that controls a threshold voltage of the transistor. For example, the first metal pattern may include at least one of a metal material (e.g., Ti, Mo, W, Cu, Al, Ta, Ru, Ir, Co, etc.) and a metal nitride (e.g., a nitride of Ti, Mo, W, Cu, Al, Ta, Ru, Ir, Co, etc.). For example, the first metal pattern may further include carbon (C). For example, the first metal pattern may include metal materials having different work functions.

For example, the second metal pattern may include a metal material (e.g., Ti, Mo, W, Cu, Al, Ta, Ru, Ir, Co, etc.) having lower resistance than the first metal pattern.

For example, the inner electrode PO1 of the gate electrode GE may include the first metal pattern. For example, the outer electrode PO2 of the gate electrode GE may include the first metal pattern and the second metal pattern.

A gate capping pattern GC may be provided on an upper surface of the gate electrode GE. For example, the gate capping pattern GC may include at least one of SiON, SiCN, SiOCN, and/or SiN.

External gate spacers OGS may be provided on side surfaces of the outer electrode PO2 of the gate electrode GE and may extend onto side surfaces of the gate capping pattern GC, respectively. For example, the external gate spacer OGS may include at least one of SiON, SiCN, SiOCN, and/or SiN.

A gate insulating pattern GI may be interposed between the gate electrode GE and the first to third semiconductor patterns SP1, SP2, and SP3. The gate insulating pattern GI may cover an upper surface, a lower surface, and both side surfaces of each of the first to third semiconductor patterns SP1, SP2, and SP3. The gate insulating pattern GI may be interposed between the outer electrode PO2 and the external gate spacer OGS. For example, the gate insulating pattern GI may include at least one of silicon oxide (SiO₂), silicon oxynitride (SiON), and/or a high-k material. In this specification, a high-k material is defined as a material having a higher dielectric constant than silicon oxide.

An inner gate spacer IGS may be interposed between the gate insulating pattern GI and the first source/drain pattern SD1. For example, the inner gate spacer IGS may include an insulating material.

A first interlayer insulating layer ILD1 may be provided on the substrate 200. The first interlayer insulating layer ILD1 may cover, overlap, or be on the outer gate spacers OGS, the first source/drain pattern SD1, and the second source/drain pattern SD2.

A second interlayer insulating layer ILD2 may cover, overlap, or be on the gate capping pattern GC on the first interlayer insulating layer ILD1. A third interlayer insulating layer ILD3 may be provided on the second interlayer insulating layer ILD2. For example, the first, second, and third interlayer insulating layers ILD1, ILD2, and ILD3 may include silicon oxide (SiO₂).

An active contact CA may penetrate the first and second interlayer insulating layers ILD1 and ILD2. For example, a lower portion of the active contact CA may be buried in or extend into an upper portion of at least one of the first source/drain patterns SD1. For example, a lower portion of the active contact CA may be buried in or extend into an upper portion of at least one of the second source/drain patterns SD2. For example, the active contact CA may include at least one of a metal material (e.g., Ti, Mo, W, Cu, Al, Ta, Ru, Ir, Co, etc.), a metal nitride (e.g., a nitride of Ti, Mo, W, Cu, Al, Ta, Ru, Ir, Co, etc.), and/or a metal silicide (e.g., a silicide of Ti, Mo, W, Cu, Al, Ta, Ru, Ir, etc.).

Gate contacts (not shown) may penetrate or extend into the second interlayer insulating layer ILD2 and the gate capping pattern GC in the third direction D3. Each of the gate contacts may be buried on an upper portion of the outer electrode PO2 of the gate electrode GE. For example, the gate contacts may include at least one of a metal material (e.g., Ti, Mo, W, Cu, Al, Ta, Ru, Ir, Co, etc.) and/or a metal nitride (e.g., a nitride of Ti, Mo, W, Cu, Al, Ta, Ru, Ir, Co, etc.).

Metal patterns MT may be provided in the third interlayer insulating layer ILD3. Via patterns VIA may be interposed between the metal patterns MT and the active contacts CA, and between the metal patterns MT and the gate contacts. For example, although not shown in the drawing, each of the metal patterns MT and the via patterns VIA may be provided in multiple layers, and each metal pattern MT and each via pattern VIA may be alternately stacked. The metal patterns MT and the via patterns VIA may include a metal material (e.g., Ti, Mo, W, Cu, Al, Ta, Ru, Ir, Co, etc.).

A power transmission network layer PDN may be provided on a lower surface of a substrate 200. The power transmission network layer PDN may include a plurality of lower wirings (not shown) electrically connected to the first source/drain pattern SD1 and the second source/drain pattern SD2 through a backside conductive contact BCA described below. As an example, the power transmission network layer PDN may include a wiring network for applying a source voltage. As an example, the power transmission network layer PDN may include a wiring network for applying a drain voltage.

The backside conductive contact BCA may penetrate or extend into the substrate 200 and the first insulating pattern IP1 and may be inserted into or extend into at least one of the first source/drain patterns SD1. The backside conductive contact BCA may penetrate or extend into the substrate 200 and the second insulating pattern IP2, and may be inserted into or extend into at least one of the second source/drain patterns SD2. The backside conductive contact BCA may be interposed between the first source/drain pattern SD1 and the power transmission network layer PDN, or between the second source/drain pattern SD2 and the power transmission network layer PDN. Accordingly, the first source/drain pattern SD1 may be electrically connected to the power transmission network layer PDN through the backside conductive contact BCA. Similarly, the second source/drain pattern SD2 may be electrically connected to the power transmission network layer PDN through the backside conductive contact BCA.

For example, the backside conductive contact BCA may include at least one of a metal material (e.g., Ti, Mo, W, Cu, Al, Ta, Ru, Ir, Co, etc.) and/or a metal nitride (e.g., a nitride of Ti, Mo, W, Cu, Al, Ta, Ru, Ir, Co, etc.).

An interface layer IF may be interposed between the backside conductive contact BCA and the first source/drain pattern SD1. For example, the interface layer IF may include a metal silicide (e.g., a silicide of Ti, Mo, W, Cu, Al, Ta, Ru, Ir, etc.). Accordingly, a contact resistance between the backside conductive contact BCA and the first source/drain pattern SD1 may be reduced. Although not shown in the drawing, a metal silicide may be interposed between the backside conductive contact BCA and the second source/drain pattern SD2.

Referring to FIGS. 1, 3A and 3B, the backside conductive contact BCA may include a first region BCA1 penetrating the first pattern T1 of the first source/drain pattern SD1, a second region BCA2 on the first region BCA1, and a third region BCA3 below the first region BCA1. The second region BCA2 of the backside conductive contact BCA may be embedded in the second pattern T2 of the first source/drain pattern SD1. The third region BCA3 of the backside conductive contact BCA may be interposed between the first region BCA1 of the backside conductive contact BCA and the power transmission network layer PDN.

The second region BCA2 of the backside conductive contact BCA may protrude in a direction parallel to the upper surface of the substrate 200 more than the first region BCA1 of the backside conductive contact BCA. The backside conductive contact BCA may have a first side surface S1, a second side surface S2, and a third side surface S3. The first side surface S1 of the backside conductive contact BCA may be a side surface of the first region BCA1 of the backside conductive contact BCA. The second side surface S2 of the backside conductive contact BCA may be a side surface of the second region BCA2 of the backside conductive contact BCA. The third side surface S3 of the backside conductive contact BCA may be a side surface of the third region BCA3 of the backside conductive contact BCA. The second side surface S2 may protrude in a direction parallel to the upper surface of the substrate 200 more than the first side surface S1. Accordingly, a contact area between the second region BCA2 of the backside conductive contact BCA and the interface layer IF may increase. As a result, the area of the second region BCA2 of the backside conductive contact BCA connected to the first source/drain pattern SD1 through the interface layer IF may increase, and a resistance therebetween may decrease. Accordingly, electrical characteristics of the semiconductor device may be improved.

A portion of the second region BCA2 of the backside conductive contact BCA may be adjacent to the first pattern T1 of the first source/drain pattern SD1 in the third direction D3. The portion of the second region BCA2 of the backside conductive contact BCA may be spaced apart from the first insulating pattern IP1 in the third direction D3 with the first pattern T1 of the first source/drain pattern SD1 interposed therebetween. The portion of the second region BCA2 of the backside conductive contact BCA may be spaced apart from the first pattern T1 of the first source/drain pattern SD1 with the interface layer IF interposed therebetween.

For example, a width of each of the first region BCA1 and the third region BCA3 of the backside conductive contact BCA in the first direction D1 may become smaller toward the third direction D3. For example, a width of the second region BCA2 of the backside conductive contact BCA in the first direction D1 may become larger toward the third direction D3 and then become smaller again. The interface layer IF may cover the first region BCA1 of a backside conductive contact BCA and extend between the second region BCA2 of the backside conductive contact BCA and the first pattern T1 of a first source/drain pattern SD1.

The interface layer IF may be spaced apart from the first insulating pattern IP1 in the third direction D3 with the first pattern T1 of the first source/drain pattern SD1 interposed therebetween. The interface layer IF may be in contact with each of the first region BCA1 of the backside conductive contact BCA, the second region BCA2 of the backside conductive contact BCA, the first pattern T1 and the second pattern T2 of the first source/drain pattern SD1, respectively. The interface layer IF may cover a lower surface BI of the second region BCA2 of the backside conductive contact BCA.

The interface layer IF may include a first region IF1 covering the first region BCA1 of the backside conductive contact BCA and a second region IF2 covering the second region BCA2 of the backside conductive contact BCA. The second region IF2 of the interface layer IF may protrude in a direction parallel to the upper surface of the substrate 200 more than the first region IF1 of the interface layer IF. For example, an outer surface of the second region IF2 of the interface layer IF may protrude in a direction parallel to the upper surface of the substrate 200 more than the third side surface S3 of a third region BCA3 of the backside conductive contact BCA. The second region IF2 of the interface layer IF may be continuously connected to the first region IF1 of the interface layer IF. The second region IF2 of the interface layer IF may be positioned at a higher vertical level than the first region IF1 of the interface layer IF. The second region IF2 of the interface layer IF may be spaced apart from the first semiconductor pattern SP1 in the first direction D1 with the first pattern T1 of the first source/drain pattern SD1 interposed therebetween.

The first pattern T1 of the first source/drain pattern SD1 may have a first inner surface IS1 in contact with the second region IF2 of the interface layer IF and a second inner surface IS2 in contact with the first region IF1 of the interface layer IF. The first inner surface IS1 of the first pattern T1 of the first source/drain pattern SD1 may be adjacent to the second side surface S2 of the backside conductive contact BCA. The second inner surface IS2 of the first pattern T1 of the first source/drain pattern SD1 may be adjacent to the first side surface S1 of the backside conductive contact BCA.

As the second region IF2 of the interface layer IF protrudes in a direction parallel to the upper surface of the substrate 200 more than the first region IF1 of the interface layer IF, the first inner surface IS1 of the first pattern T1 of the first source/drain pattern SD1 may have a profile recessed in the direction. In other words, the first inner surface IS1 of the first pattern T1 of the first source/drain pattern SD1 may have a concave profile in the above direction. In addition, the first inner surface IS1 of the first pattern T1 of the first source/drain pattern SD1 may protrude in a direction parallel to the upper surface of the substrate 200 more than the second inner surface IS2.

The first inner surface IS1 of the first pattern T1 of the first source/drain pattern SD1 may be positioned at a higher vertical level than the second inner surface IS2 and may be continuously connected to each other.

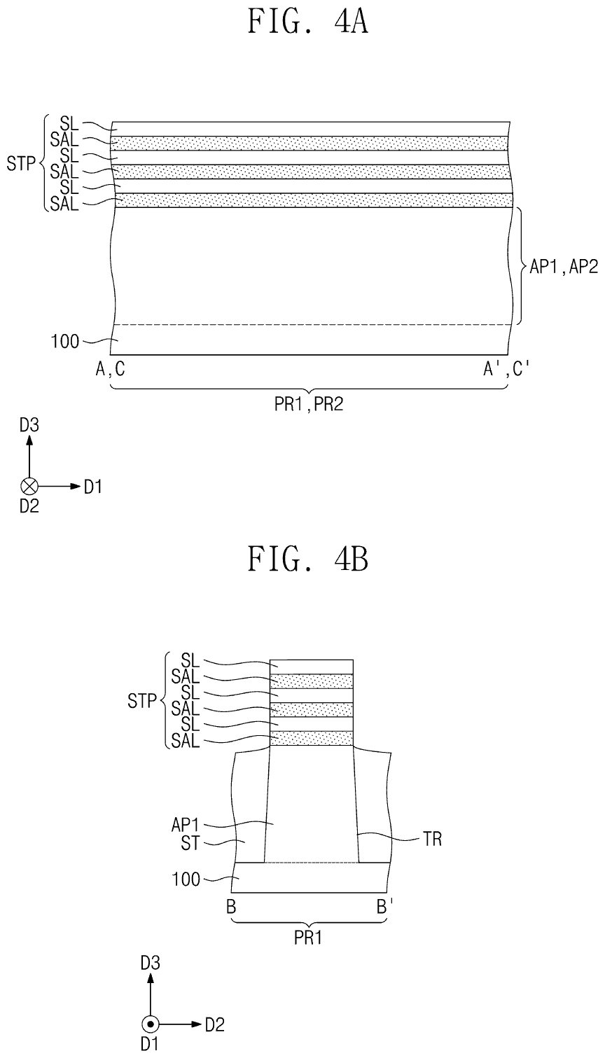

Hereinafter, a method of manufacturing a semiconductor device according to some embodiments of the inventive concept will be described with reference to FIGS. 4A, 4B, 5, 6A, 6B, 6C, 7, 8A, 8B, 8C, 9A, and 9B. For simplicity of explanation, descriptions of contents overlapping with the above contents will be omitted, and differences from the above contents will be mainly described.

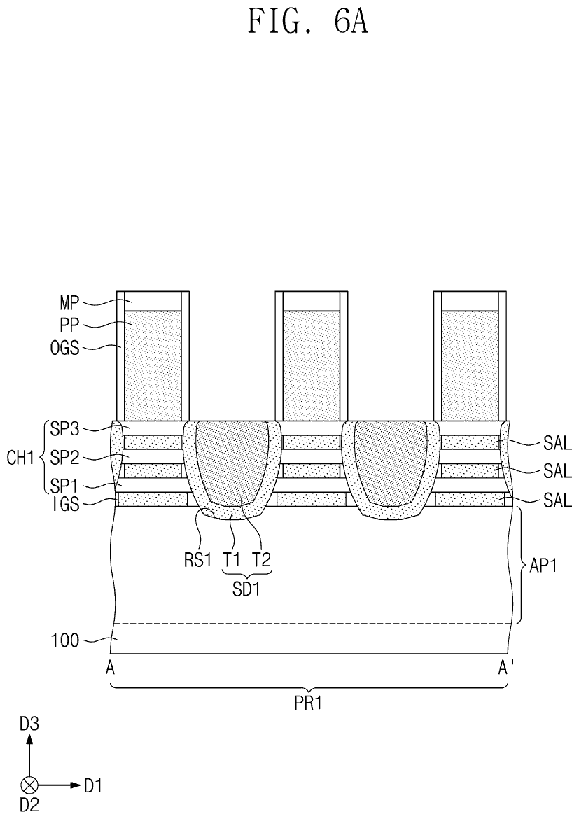

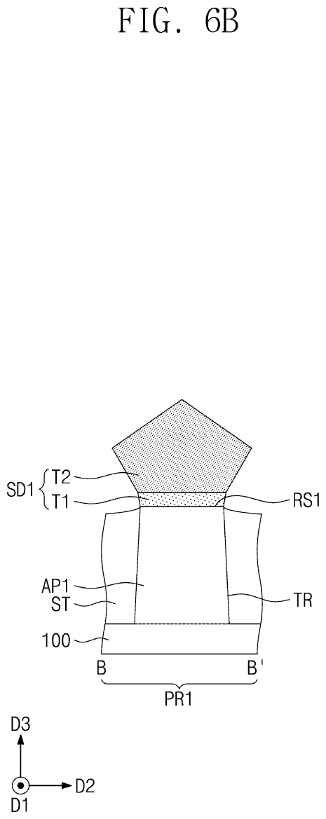

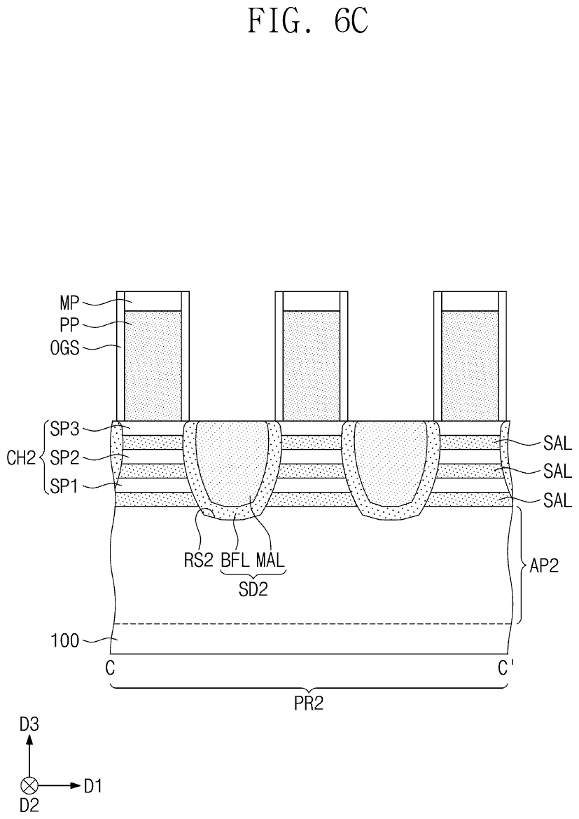

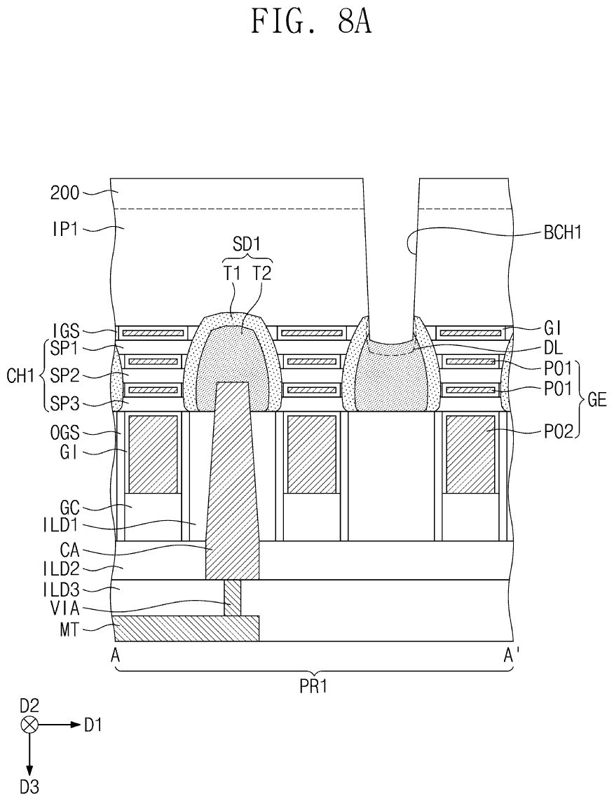

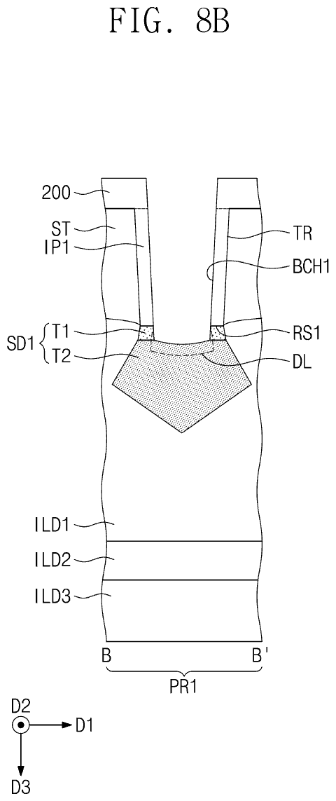

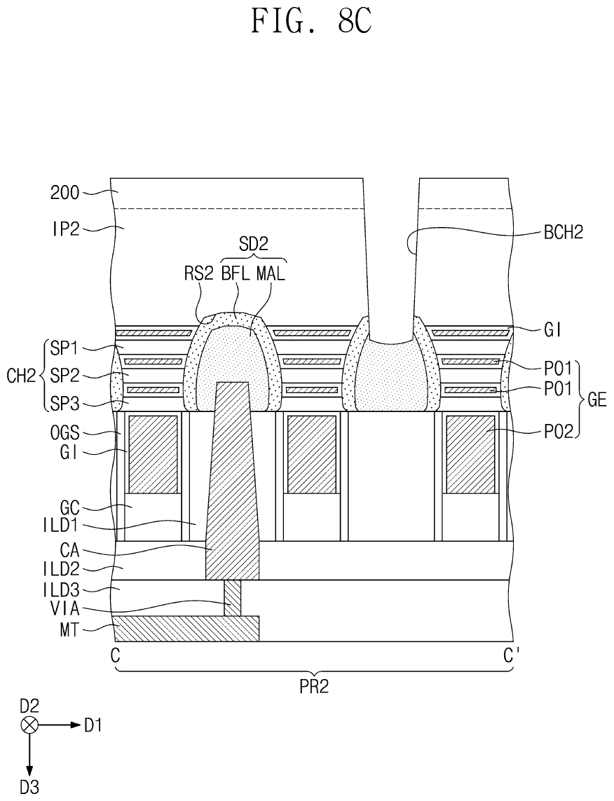

FIGS. 4A, 4B, 5, 6A, 6B, 6C, 7, 8A, 8B, 8C, 9A, and 9B are views illustrating a method of manufacturing a semiconductor device according to some embodiments of the inventive concept. In detail, FIGS. 4A, 5, 6A, 7, 8A, and 9A are cross-sectional views corresponding to line A-A′ of FIG. 1, respectively. FIGS. 4B, 6B, 8B, and 9B are cross-sectional views corresponding to line B-B′ of FIG. 1, respectively. FIGS. 6C and 8C are cross-sectional views corresponding to line C-C′ of FIG. 1, respectively.

First, referring to FIGS. 1, 4A, and 4B, a semiconductor substrate 100 including a first region PR1 and a second region PR2 may be provided. For example, the semiconductor substrate 100 may be a semiconductor substrate including a semiconductor material, such as a silicon single crystal substrate, a silicon-germanium substrate, or an SOI substrate. Stacked patterns STP may be formed on the first region PR1 and the second region PR2. For example, forming the stacked patterns STP may include alternately stacking semiconductor layers SL and sacrificial layers SAL on a semiconductor substrate 100, forming mask patterns (not shown) extending in a first direction D1, and performing a patterning process using the mask patterns as an etching mask. During the patterning process, a portion of the semiconductor substrate 100 may be removed together, and trenches TR defining the first active pattern AP1 and the second active pattern AP2 may be formed.

The first active pattern AP1 may be formed on the first region PR1, and the second active pattern AP2 may be formed on the second region PR2. The first and second active patterns AP1 and AP2 may extend in the first direction D1, respectively. A device isolation patterns ST may be formed to fill the trenches TR.

The sacrificial layers SAL may include a material that may have an etching selectivity with a material of the semiconductor layers SL. Accordingly, when the sacrificial layers SAL are removed during a removal process described below, the semiconductor layers SL may not be removed or may be removed to a small extent. For example, the semiconductor layers SL may include one of silicon (Si), germanium (Ge), and silicon-germanium (SiGe), and the sacrificial layers SAL may include another one of silicon (Si), germanium (Ge), and/or silicon-germanium (SiGe) different from the material of the semiconductor layers SL.

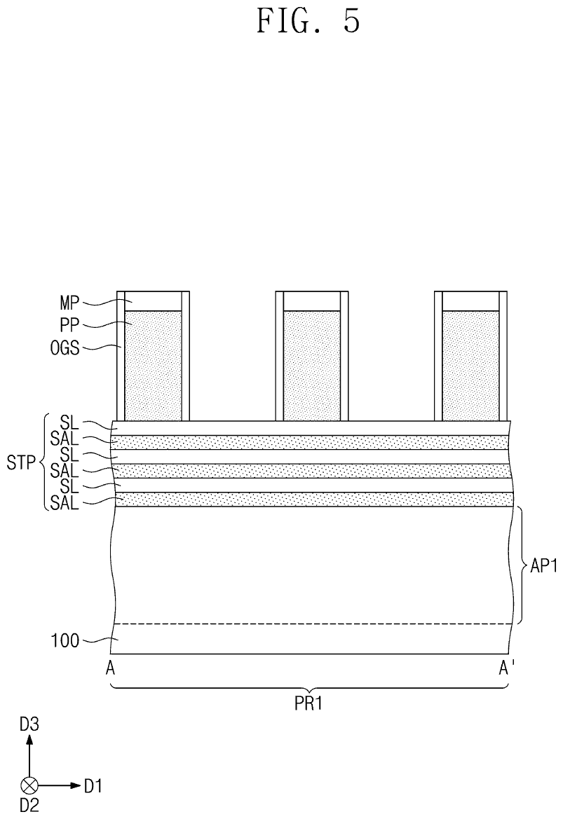

Referring to FIGS. 1 and 5, sacrificial patterns PP may be formed on the semiconductor substrate 100 to extend in a second direction D2, respectively. The sacrificial patterns PP may be formed to cover or overlap upper surfaces of the device isolation patterns ST described with reference to FIG. 4B, side surfaces and upper surfaces of the stacked patterns STP. For example, forming the sacrificial patterns PP may include forming a sacrificial layer (not shown) on the entire surface of the semiconductor substrate 100, forming hard mask patterns MP on the sacrificial layer, and removing a portion of the sacrificial layer using the hard mask patterns MP as an etching mask to form the sacrificial patterns PP. For example, the sacrificial pattern PP may include polysilicon. Thereafter, external gate spacers OGS may be formed on side surfaces of the sacrificial patterns PP.

Referring to FIG. 1 and FIGS. 6A,6 B, and 6C, first recesses RS1 may be formed in the stacked pattern STP on the first active pattern AP1. Second recesses RS2 may be formed in the stacked pattern STP on the second active pattern AP2. For example, the first and second recesses RS1 and RS2 may be formed by removing a portion of the stacked pattern STP using hard mask patterns MP as an etching mask.

The semiconductor layers SL on the first active pattern AP1 may be separated into first channel patterns CH1 spaced apart from each other in a first direction D1 by the first recesses RS1. The semiconductor layers SL on the second active pattern AP2 may be separated into second channel patterns CH2 spaced apart from each other in the first direction D1 by the second recesses RS2.

A portion of the sacrificial layer SAL exposed by the first recess RS1 may be replaced with an insulating material, and thus, internal gate spacers IGS may be formed on both sides of the sacrificial layer SAL.

First source/drain patterns SD1 may be formed in the first recesses RS1. For example, forming the first source/drain pattern SD1 may include forming a first pattern T1 conformally covering or overlapping an inner surface of the first recess RS1 and forming a second pattern T2 filling the first recess RS1. The first pattern T1 of the first source/drain pattern SD1 may have an etching selectivity with respect to the semiconductor substrate 100 and the first active pattern AP1, respectively.

For example, during the process of forming the first source/drain pattern SD1, impurities (e.g., phosphorus, arsenic, or antimony) that causes the n-type pattern to be formed may be in-situ injected into the first source/drain pattern SD1. As another example, after the first source/drain pattern SD1 is formed, the impurities may be injected into the first source/drain pattern SD1.

The second source/drain patterns SD2 may be formed in the second recesses RS2. For example, during the process of forming the second source/drain pattern SD2, impurities (for example, boron, gallium, or indium) to have a p-type may be implanted in-situ into the second source/drain pattern SD2. As another example, after the second source/drain pattern SD2 is formed, the impurities may be implanted into the second source/drain pattern SD2.

The second source/drain pattern SD2 may include a buffer layer BFL and a main layer MAL on the buffer layer BFL. For example, each of the buffer layer BFL and the main layer MAL may include silicon-germanium (SiGe). The buffer layer BFL may include a relatively low concentration of germanium (Ge). The main layer MAL may include a relatively high concentration of germanium (Ge). As another example, the buffer layer BFL may include only silicon (Si).

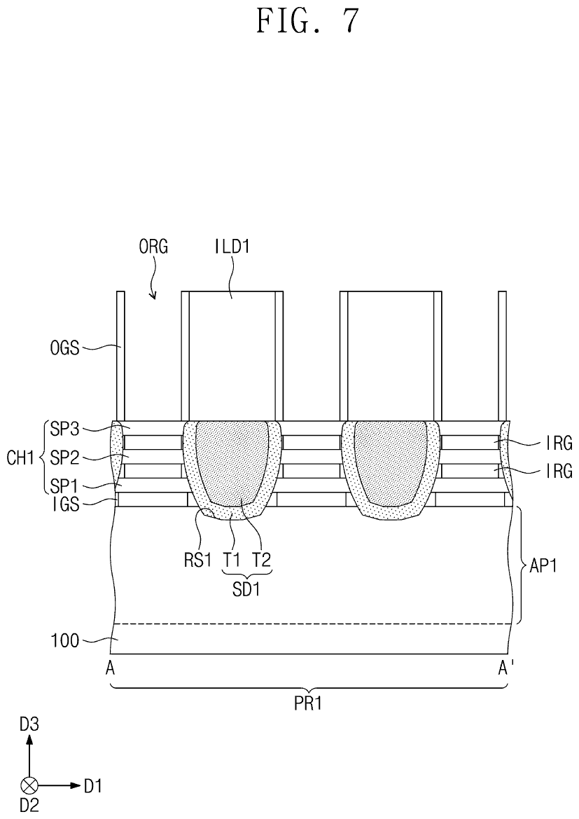

Referring to FIGS. 1 and 7, a first interlayer insulating layer ILD1 may be formed to cover or overlap the first source/drain patterns SD1, the second source/drain patterns SD2 (refer to FIG. 6C), the hard mask patterns MP, and the external gate spacers OGS. Thereafter, the first interlayer insulating layer ILD1 on upper surfaces of the sacrificial patterns PP may be removed. During the removal process, the hard mask patterns MP may be removed together, and the sacrificial patterns PP may be exposed.

Thereafter, the exposed sacrificial patterns PP may be removed, and outer regions ORG may be formed in the regions where the sacrificial patterns PP are removed. The first channel patterns CH1, the second channel patterns CH2 (refer to FIG. 6C) and the sacrificial layers SAL may be exposed to the outside by the outer regions ORG.

Then, the exposed sacrificial layers SAL may be selectively removed. In this case, the first, second, and third semiconductor patterns SP1, SP2, and SP3 may not be removed or may be removed to a small extent due to the high etching selectivity of the sacrificial layers SAL.

Inner regions IRG may be formed in the regions where the sacrificial layers SAL are removed. In detail, the inner regions IRG may be formed between the first to third semiconductor patterns SP1, SP2, and SP3.

A gate insulating pattern GI may be formed in each of the inner regions IRG and the outer region ORG. The gate insulating pattern GI may be formed to surround each of the first to third semiconductor patterns SP1, SP2, and SP3.

Referring to FIG. 1 and FIGS. 8A, 8B, and 8C, a gate electrode GE may be formed on the gate insulating pattern GI. The gate electrode GE may include an inner electrode PO1 formed in each of the inner regions IRG and an outer electrode PO2 formed in the outer region ORG. Thereafter, a gate capping pattern GC may be formed on the outer electrode PO2 of the gate electrode GE.

A second interlayer insulating layer ILD2 may be formed on the first interlayer insulating layer ILD1 and the gate capping pattern GC.

An active contact CA may be formed to penetrate or extend into the first interlayer insulating layer ILD1 and the second interlayer insulating layer ILD2, and may be electrically connected to at least one of the first and second source/drain patterns SD1 and SD2.

Gate contacts (not shown) may be formed to penetrate or extend into the second interlayer insulating layer ILD2 and the gate capping pattern GC, and may be electrically connected to the gate electrodes GE.

A third interlayer insulating layer ILD3 may be formed on the second interlayer insulating layer ILD2. Metal patterns MT and via patterns VIA may be formed in the third interlayer insulating layer ILD3.

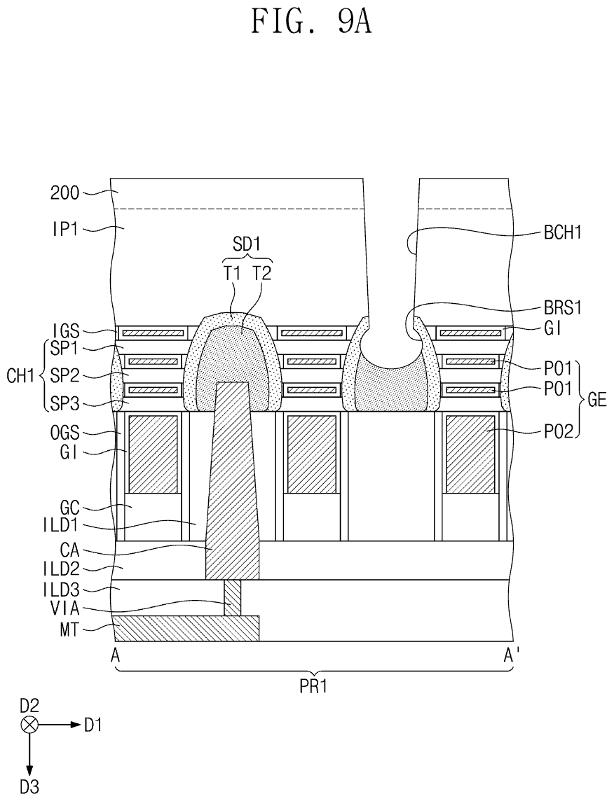

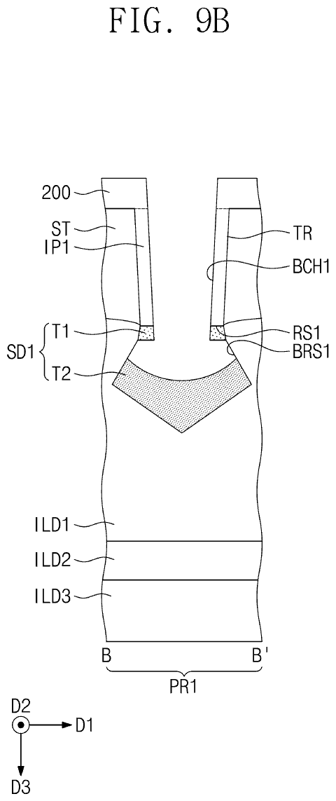

After the BEOL process is completed, the semiconductor substrate 100 (refer to FIG. 7) may be flipped upside down. As the semiconductor substrate 100 (refer to FIG. 7) is upside-down inverted, when describing with reference to FIGS. 8A, 8B, 8C, 9A, and 9B below, each of the ‘upper surface’ and the ‘upper portion’ may mean each of the ‘lower surface’ and the ‘lower portion’ from the semiconductor device whose manufacturing has been completed described with reference to FIGS. 2A and 2B, and each of the ‘lower surface’ and the ‘lower portion’ may mean each of the ‘upper surface’ and the ‘upper portion’ from the semiconductor device whose manufacturing has been completed described with reference to FIGS. 2A and 2B.

After the semiconductor substrate 100 (refer to FIG. 7) is upside-down inverted, a removal process for the semiconductor substrate 100 (refer to FIG. 7) may be performed. In this case, the first pattern T1 of the first source/drain pattern SD1 may have an etching selectivity with the semiconductor substrate 100 (refer to FIG. 7), and thus the first pattern T1 of the first source/drain pattern SD1 may not be removed during the removal process. In other words, during the removal process, the first pattern T1 of the first source/drain pattern SD1 in the first region PR1 may be used as an etching stop layer. Accordingly, the removal process of the semiconductor substrate 100 (refer to FIG. 7) may be facilitated. As a result, the semiconductor substrate 100 (refer to FIG. 7) may not remain unnecessarily, and an unnecessary residue of the semiconductor substrate 100 (refer to FIG. 7) may not be utilized as a path for leakage current. Therefore, electrical characteristics of the semiconductor device may be improved.

Thereafter, a substrate 200 may be formed in a region where a semiconductor substrate 100 (refer to FIG. 7) is removed. A portion of the substrate 200 may form the first insulating pattern IP1 and the second insulating pattern IP2.

Then, a portion of each of the substrate 200 and the first insulating pattern IP1 may be removed to form a first backside contact hole BCH1. A portion of each of the substrate 200 and the second insulating pattern IP2 may be removed to form a second backside contact hole BCH2. For example, the process of forming the first backside contact hole BCH1 and the process of forming the second backside contact hole BCH2 may be performed simultaneously.

The first backside contact hole BCH1 may penetrate or extend into the first pattern T1 of the first source/drain pattern SD1. The second pattern T2 of the first source/drain pattern SD1 may be exposed to the outside by an inner surface of the first backside contact hole BCH1. During a process for forming the first backside contact hole BCH1 (e.g., an etching process), a damage layer DL may be formed in a portion of the first source/drain pattern SD1 exposed to the outside by the first backside contact hole BCH1. The damage layer DL may include a defect caused by the etching process. When a conductive material is formed inside the first backside contact hole BCH1 without a removal process or a curing process for the damage layer DL, a contact resistance between the first source/drain pattern SD1 and the conductive material may increase due to the damage layer DL.

Referring to FIG. 1, FIG. 9A and FIG. 9B, before forming a conductive material inside the first backside contact hole BCH1, the damage layer DL may be removed to form a first backside recess BRS1 inside the first source/drain pattern SD1. A portion of an inner surface of the first pattern T1 of the first source/drain pattern SD1 may be recessed by the first backside recess BRS1.

The first backside recess BRS1 may be formed below the first backside contact hole BCH1 and may be continuously connected to the first backside contact hole BCH1. For example, the process of removing the damage layer DL may include at least one of an etching process and a cleaning process.

According to the inventive concept, the removal process for the damage layer DL inside the first source/drain pattern SD1 formed during the process of forming the first backside contact hole BCH1 may be performed. Accordingly, a defect inside the first source/drain pattern SD1 may be removed. As a result, a contact resistance between a conductive material formed in the first backside contact hole BCH1 and the first source/drain pattern SD1 may be improved. Accordingly, electrical characteristics of the semiconductor device may be improved.

In addition, the removal process may be performed for the damage layer DL, and the first backside recess BRS1 may be formed on the first source/drain pattern SD1. Accordingly, the contact area between the conductive material formed in the first backside contact hole BCH1 and the first source/drain pattern SD1 may increase. As a result, a contact resistance between the conductive material and the first source/drain pattern SD1 may be improved. Accordingly, electrical characteristics of the semiconductor device may be improved.

Although not shown in the drawings, as an example, during the removal process for the first backside recess BRS1, a second backside recess (not shown) may be formed on the second source/drain pattern SD2. Characteristics of the second backside recess may be the same/similar to characteristics of the first backside recess BRS1.

Referring again to FIGS. 1, 2A, and 2B, an additional sacrificial layer (not shown) may be formed in each of the first backside recess BRS1 (refer to FIGS. 9A and 9B) and the second backside recess. As an example, the additional sacrificial layer may include SiGe.

Thereafter, the additional sacrificial layer in the first backside recess BRS1 (refer to FIGS. 9A and 9B) may be removed. The additional sacrificial layer in the second backside recess may remain without being removed. A backside conductive contact BCA may be formed to partially or completely fill the inside of each of the first backside recess BRS1 (refer to FIGS. 9A and 9B), the first backside contact hole BCH1 (refer to FIGS. 9A and 9B), the second backside recess, and the second backside contact hole BCH2 (refer to FIG. 8C).

An interface layer IF may be formed between the backside conductive contact BCA and the first source/drain pattern SD1. For example, the interface layer IF may be formed during a process of forming the backside conductive contact BCA.

Due to a profile of the first backside recess BRS1, a portion of each of the backside conductive contact BCA and the interface layer IF may protrude in a direction parallel to an upper surface of the substrate 200. A power transmission network layer PDN may be formed on the substrate 200.

According to the inventive concept, the removal process for the damage layer inside the source/drain pattern formed during the process of forming the backside contact hole may be performed. Accordingly, the defect inside the source/drain pattern may be removed. As a result, the contact resistance between the conductive material formed in the backside contact hole and the source/drain pattern may be improved. Therefore, the electrical characteristics of the semiconductor device may be improved.

In addition, the removal process may be performed for the damage layer, thereby forming the backside recess on the source/drain pattern. Accordingly, the contact area between the conductive material formed in the backside contact hole and the source/drain pattern may increase. As a result, the contact resistance between the conductive material and the source/drain pattern may be improved. Therefore, the electrical characteristics of the semiconductor device may be improved.

The first source/drain pattern may include the first pattern and the second pattern including the material different from the first pattern. The first pattern of the first source/drain pattern may have the etching selectivity with respect to the semiconductor substrate. Accordingly, the first pattern of the first source/drain pattern may be used as the etching stop layer during the removal process of the semiconductor substrate, thereby facilitating the removal process of the semiconductor substrate. In addition, the first pattern of the first source/drain pattern may prevent the second pattern from being unnecessarily diffused into the channel pattern.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a power transmission network layer on a first surface of a substrate;
a source/drain pattern on the substrate, the source/drain pattern comprising a first pattern including a first material and a second pattern including a second material that is different from the first material; and
a backside conductive contact that extends into the substrate and into the source/drain pattern,
wherein the backside conductive contact includes a first region that extends into the first pattern of the source/drain pattern and a second region on the first region of the backside conductive contact, and
wherein the second region of the backside conductive contact has a second width that is greater than a first width of the first region of the backside conductive contact in a direction parallel to a second surface of the substrate.

2. The semiconductor device of claim 1, further comprising:
an interface layer on a side surface of the first region of the backside conductive contact, wherein the interface layer extends between the second region of the backside conductive contact and the first pattern of the source/drain pattern.

3. The semiconductor device of claim 1, further comprising:
an interface layer between the backside conductive contact and the first pattern of the source/drain pattern,
wherein the interface layer includes a first region and a second region that protrudes in the direction parallel to the second surface of the substrate more than the first region of the interface layer.

4. The semiconductor device of claim 1, further comprising:
an interface layer on an inner surface of the first pattern of the source/drain pattern; and
a channel pattern on a side surface of the source/drain pattern,
wherein the channel pattern includes a plurality of semiconductor patterns on the substrate, and
wherein the interface layer is spaced apart from at least one of the semiconductor patterns in the direction parallel to the second surface of the substrate with the first pattern of the source/drain pattern therebetween.

5. The semiconductor device of claim 1, wherein the first pattern of the source/drain pattern has a first side surface adjacent to a side surface of the second region of the backside conductive contact, and
wherein the semiconductor device further comprises an interface layer on the first side surface of the first pattern of the source/drain pattern.

6. The semiconductor device of claim 5, wherein the first pattern of the source/drain pattern has a second side surface adjacent to a side surface of the first region of the backside conductive contact, and
wherein the first side surface of the first pattern of the source/drain pattern protrudes in the direction parallel to the second surface of the substrate more than the second side surface of the first pattern of the source/drain pattern.

7. The semiconductor device of claim 5, further comprising:
an insulating pattern on the substrate,
wherein the interface layer is spaced apart from the insulating pattern in a direction perpendicular to the second surface of the substrate with the first pattern of the source/drain pattern therebetween.

8. The semiconductor device of claim 1, further comprising:
an insulating pattern on the substrate,
wherein the first pattern of the source/drain pattern is between the second region of the backside conductive contact and the insulating pattern.

9. The semiconductor device of claim 1, wherein the first pattern of the source/drain pattern comprises SiGe, and
wherein the second pattern of the source/drain pattern comprises Si.

10. The semiconductor device of claim 1, wherein the source/drain pattern comprises an n-conductive impurity.

11. A semiconductor device comprising:
a power transmission network layer on a first surface of a substrate;
a source/drain pattern on the substrate, the source/drain pattern comprising a first pattern including a first material and a second pattern including a second material that is different from the first material;
a backside conductive contact that extends into the substrate and into the source/drain pattern; and
an interface layer between the first pattern of the source/drain pattern and the backside conductive contact,
wherein the interface layer comprises a first region that has a first width and a second region that has a second width that is greater than the first width in a direction parallel to an second surface of the substrate.

12. The semiconductor device of claim 11, wherein the second region of the interface layer is a first distance from the substrate that is greater than a second distance of the first region from the substrate.

13. The semiconductor device of claim 11, wherein the first pattern of the source/drain pattern includes a first side surface in contact with the second region of the interface layer and a second side surface in contact with the first region of the interface layer.

14. The semiconductor device of claim 13, wherein the first side surface of the first pattern of the source/drain pattern protrudes more than the second side surface of the first pattern of the source/drain pattern in the direction parallel to the second surface of the substrate.

15. The semiconductor device of claim 11, further comprising:
a channel pattern on a side surface of the source/drain pattern,
wherein the channel pattern includes a plurality of semiconductor patterns on the substrate, and
wherein the second region of the interface layer is spaced apart from at least one of the semiconductor patterns in the direction parallel to the second surface of the substrate with the first pattern of the source/drain pattern therebetween.

16. The semiconductor device of claim 11, wherein the first pattern of the source/drain pattern is spaced apart from the backside conductive contact in a direction perpendicular to the second surface of the substrate with the interface layer therebetween.

17. The semiconductor device of claim 11, further comprising:
an insulating pattern on the substrate,
wherein the interface layer is spaced apart from the insulating pattern in a direction perpendicular to the second surface of the substrate with the first pattern of the source/drain pattern therebetween.

18. The semiconductor device of claim 11, wherein the interface layer is between a portion of the backside conductive contact that extends into the second pattern of the source/drain pattern and the first pattern of the source/drain pattern.

19. A semiconductor device comprising:
a power transmission network layer on a first surface of a substrate;
a source/drain pattern on the substrate, the source/drain pattern comprising a first pattern including a first material and a second pattern including a second material that is different from the first material;
a channel pattern on a side surface of the source/drain pattern, the channel pattern including a plurality of semiconductor patterns on the substrate;
a gate electrode on the channel pattern;
a backside conductive contact that extends into the substrate and into the source/drain pattern; and
an interface layer between the first pattern of the source/drain pattern and the backside conductive contact,
wherein the backside conductive contact includes a first region that extends into the first pattern of the source/drain pattern and a second region on the first region, and
wherein the second region of the backside conductive contact has a second width that is greater than a first width of the first region of the backside conductive contact in a direction parallel to a second surface of the substrate.

20. The semiconductor device of claim 19, wherein the interface layer includes a first region and a second region protruding more than the first region of the interface layer in the direction parallel to the second surface of the substrate.
